(19) United States
(12) Patent Application Publication
(10) Pub. No.: US 2010/0020257 A1
(43) Pub. Date: Jan. 28, 2010

(54) Liquid crystal display device and manufacturing method thereof

(75) Inventors: Sahng-Ik Jun, Yongin-si (KR); Seong-Young Lee, Anyang-si (KR); Yoon-Jang Kim, Suwon-si (KR); Kee-bum Park, Cheonan-si (KR)

Correspondence Address: Haynes and Boone, LLP;IP Section, 2323 Victory Avenue, SUITE 700, Dallas, TX, 75219, US

(73) Assignee: Samsung Electronics Co., Ltd.

(21) Appl. No.: 12/220,472

(22) Filed: Jul. 23, 2008

(51) Int. Cl. G02F 1/136; H01L 21/336

(52) U.S. Cl. 349/44; 438/158; 257/E21.414

(57) ABSTRACT

A liquid crystal display device including a first substrate, a second substrate which faces the first substrate and a liquid crystal layer which is interposed between the first and second substrates. The first substrate comprises an insulating substrate, a gate line which is disposed on the insulating substrate, data wires which comprises first and second data lines insulatedly crossing the gate line. The first substrate includes a first drain electrode electrically connected with the first data line, and a second drain electrode electrically connected with the second data line, a pixel electrode which comprises a first sub-pixel electrode electrically connected with one of the first and second drain electrodes, and a second sub-pixel electrode separated from the first sub-pixel electrode and electrically connected with the other one of the first and second drain electrodes. A semiconductor layer is disposed between the data wires and the insulating substrate. An ohmic contact layer is disposed between the semiconductor layer and the data wires, and directly contacts the semiconductor layer and the data wires. A light blocking layer is disposed between at least a part of the data wires and the insulating substrate.

### CROSS-REFERENCE TO RELATED APPLICATIONS

This application claims priority from Korean Patent Application No. 10-2007-0076768, filed on Jul. 31, 2007, in the Korean Intellectual Property Office, the disclosure of which is incorporated herein by reference.

### BACKGROUND OF THE INVENTION

1. Field of the Invention

Apparatuses and methods consistent with the present invention relate to a liquid crystal display device and a manufacturing method thereof.

2. Description of the Related Art

A liquid crystal display device includes a liquid crystal panel and a light source which is disposed behind the liquid crystal panel and emits light thereto. The liquid crystal panel includes a first substrate having a pixel electrode, a second panel facing the first panel, and a liquid crystal layer interposed between the first and second substrates. Liquid crystal molecules in the liquid crystal layer adjust transmittance of light emitted by the light source, according to a data voltage applied to the pixel electrode, and display an image.

The first substrate includes data wires which supply power to the pixel electrode, and a thin film transistor which switches on/off power supplied to a pixel and includes a semiconductor layer.

Recently, a method of forming the semiconductor layer and the data wires by using a single mask has been developed. In this case, the semiconductor layer is disposed below the data wires.

However, if the semiconductor layer disposed below the data wires receives light from the light source, permittivity of the semiconductor layer rises. Then, an electric capacitance between the data wires, disposed on the semiconductor layer, and the pixel electrode rises, too, thereby lowering a voltage supplied to the pixel electrode through the data wires.

### SUMMARY OF THE INVENTION

Accordingly, it is an aspect of the present invention to provide a liquid crystal display device which minimizes light supplied to a semiconductor layer disposed below data wires, and a manufacturing method thereof.

Additional aspects and/or advantages of the present invention are set forth in the description which follows and, it will be obvious from the description, or may be learned by practice of the present invention.

The foregoing and/or other aspects of the present invention are also achieved by providing a liquid crystal display device, comprising: a first substrate; a second substrate which faces the first substrate; a liquid crystal layer which is interposed between the first and second substrates; the first substrate comprising: an insulating substrate; a gate line which is disposed on the insulating substrate; data wires which comprises first and second data lines insulatedly crossing the gate line, a first drain electrode electrically connected with the first data line, and a second drain electrode electrically connected with the second data line; a pixel electrode which comprises a first sub-pixel electrode electrically connected with one of the first and second drain electrodes, and a second sub-pixel electrode separated from the first sub-pixel electrode and electrically connected with the other one of the first and second drain electrodes; a semiconductor layer which is disposed between the data wires and the insulating substrate; an ohmic contact layer which is disposed between the semiconductor layer and the data wires, and directly contacts the semiconductor layer and the data wires; and a light blocking layer which is disposed between at least a part of the data wires and the insulating substrate.

The light blocking layer may be disposed between the semiconductor layer and the insulating substrate.

A width of the light blocking layer overlapping the semiconductor layer may be wider than that of the semiconductor layer.

The light blocking layer may be disposed in the same layer as the gate line.

The light blocking layer may float.

The first substrate may comprise a thin film transistor which has a first sub-thin film transistor connected with the gate line and the first data line, and a second sub-thin film transistor connected with the gate line and the second data line; and the first sub-thin film transistor comprises the first drain electrode, and the second sub-thin film transistor comprises the second drain electrode.

The first and second sub-pixel electrodes may be bent at least once in an extension direction of the first data line or the second data line.

The liquid crystal display device may be driven at 120 Hz.

The first and second drain electrodes may apply a voltage to the pixel electrode, and polarities of the voltage may apply to the first and second sub-pixel electrodes are opposite to each other.

The first and second drain electrodes may apply a voltage to the pixel electrode, and the voltage may apply to the first pixel electrode is larger than that applied to the second sub-pixel electrode.

The first drain electrode may contact the first sub-pixel electrode, the second sub-pixel electrode surrounds the first sub-pixel electrode, and the light blocking layer may be disposed below the first drain electrode overlapping the second sub-pixel electrode.

The second sub-pixel electrode may surround the first sub-pixel electrode, the first data line may be disposed in the left side of the pixel electrode, the second data line may be disposed in the right side of the pixel electrode, the second data line may be electrically connected with the second sub-pixel electrode in one of the pair of pixel electrodes adjacent to each other toward the gate line, and the first data line may be electrically connected with the second sub-pixel electrode in the other one of the pair of pixel electrodes.

The light blocking layer may be formed corresponding to the first data line, the second data line, the first drain electrode and the second drain electrode.

The light blocking layer may be disposed in at least one of between the insulating substrate and the first drain electrode, and between the insulating substrate and the second drain electrode.

The light blocking layer may not be disposed between the second drain electrode and the insulating substrate.

The first and second drain electrodes respectively may comprise a first branch electrode elongated to contact the pixel electrode, and a second branch electrode elongated from a contact part of the pixel electrode, and the light blocking layer may not be disposed between the second branch electrode of the first drain electrode, and the insulating substrate.

The second substrate may comprise a common electrode, the pixel electrode may comprise a pixel electrode cutting pattern, the common electrode may comprise a common electrode cutting pattern, and the liquid crystal layer may be a vertically-aligned mode.

The pixel electrode may be plurally provided, and the first substrate may comprise a shield electrode which is disposed between the neighboring pixel electrodes, and is disposed in an extension direction of the first data line or the second data line.

The light blocking layer may be formed along the shield electrode, and corresponds to the first and second data lines, respectively.

The shield electrode may be in the same layer as the pixel electrode.

The foregoing and/or other aspects of the present invention are also achieved by providing a manufacturing method of a liquid crystal display device, the manufacturing method comprising: providing an insulating substrate; forming a gate metal layer on the insulating substrate; forming gate wires having a gate line and a light blocking layer by patterning the gate metal layer; forming an insulating layer on the gate wires; forming a silicon layer on the insulating layer; forming an ohmic contact silicon layer on the silicon layer; forming a data metal layer on the ohmic contact silicon layer; forming data wires which partially overlaps the light blocking layer and having a first data line and a second data line insulatedly crossing the gate line, a first drain electrode electrically connected with the first data line, and a second drain electrode electrically connected with the second data line, an ohmic contact layer and a semiconductor layer by patterning the data metal layer, the ohmic contact silicon layer and the silicon layer through a single mask; forming an organic layer on the semiconductor layer, the ohmic contact layer and the data wires; forming a transparent metal layer on the organic layer; and forming a pixel electrode which comprises a first sub-pixel electrode electrically connected with one of the first and second drain electrodes, and a second sub-pixel electrode separated from the first sub-pixel electrode and electrically connected with the other one of the first and second drain electrodes.

### BRIEF DESCRIPTION OF THE DRAWINGS

The above and other aspects of the present invention will become apparent and more readily appreciated from the following description of the embodiments, taken in conjunction with the accompanying drawings of which:

FIG. 1 is an equivalent circuit diagram of a liquid crystal display device according to an embodiment of the present invention;

FIG. 2 is a graph which illustrates visibility improving principle of the liquid crystal display device according to the present invention;

FIG. 3 is a plan view of an arrangement of a pixel of a liquid crystal display device according to a first exemplary embodiment of the present invention;

FIG. 4 is a sectional view of the pixel, taken along line IV-IV in FIG. 3;

FIG. 5 is a sectional view of the pixel, taken along line V-V in FIG. 3 [where is V-V in FIG. 3?];

FIG. 6 is a flowchart listing the process steps for a manufacturing method of a liquid crystal display device according to the first exemplary embodiment of the present invention;

FIGS. 7A to 10 illustrate the manufacturing steps of a method of manufacturing a liquid crystal display device according to the first exemplary embodiment of the present invention;

FIG. 11 is a plan view of a pixel of a liquid crystal display device according to a second exemplary embodiment of the present invention;

FIG. 12 is a plan view of a pixel of a liquid crystal display device according to a third exemplary embodiment of the present invention; and

FIG. 13 is a plan view of a pixel of a liquid crystal display device according to a fourth exemplary embodiment of the present invention.

### DETAILED DESCRIPTION OF EXEMPLARY EMBODIMENT

Hereinafter, exemplary embodiments of the present invention will be described with reference to accompanying drawings, wherein like numerals refer to like elements and repetitive descriptions will be avoided as necessary.

Hereinafter, disposing (forming) a film (i.e., a layer) “on” another film (i.e., a layer) is that a third layer is disposed or not disposed between the two films (i.e., layers).

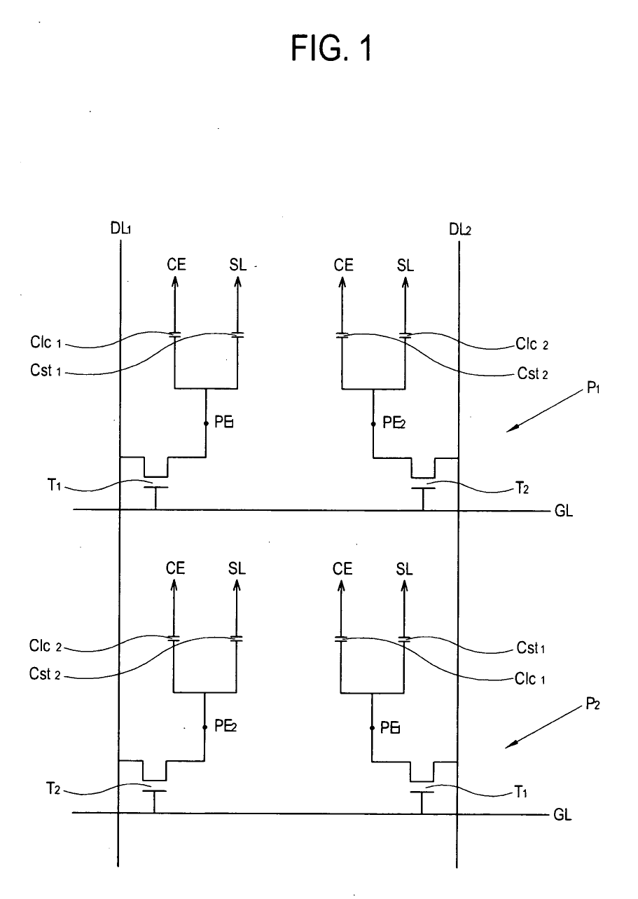

FIG. 1 is an equivalent circuit diagram of a liquid crystal display device according to an embodiment of the present invention, and illustrates two pixels P₁ and P₂ which are adjacent to each other in an extension direction of data lines DL₁ and DL₂. The respective pixels P₁ and P₂ are connected with a single gate line GL and the two data lines DL₁ and DL₂. The pixels P₁ and P₂ include two thin film transistors T₁ and T₂, respectively.

As shown therein, a first thin film transistor T₁ of the first pixel P₁ is connected with a first data line DL₁ and the gate line GL while a second thin film transistor T₂ is connected with a second data line DL₂ and the gate line GL.

The thin film transistors T₁ and T₂ are connected with the same gate line GL, and are driven at the same time. Meanwhile, the thin film transistors T₁ and T₂ are connected with different data lines DL₁ and DL₂, and output different signals.

The respective thin film transistors T₁ and T₂ are connected with liquid crystal capacitances C_{LC1} and C_{LC2}, and with storage capacitances Cst₁ and Cst₂. The liquid crystal capacitances C_{LC1} and C_{LC2} are formed between pixel electrodes PE₁ and PE₂ and common electrode CE. The storage capacitances Cst₁ and Cst₂ are formed between the pixel electrodes PE₁ and PE₂, and a storage electrode line SL.

A first sub-pixel electrode PE₁ and a second sub-pixel electrode PE₂ are separated from each other.

The second pixel P₂ has a configuration similar to that of the first pixel P₁. Meanwhile, the first thin film transistor T₁ is connected with the first data line DL₁ and the second sub-pixel electrode PE₂. The second thin film transistor T₂ is connected with the second data line DL₂ and the first sub-pixel electrode PE₁.

That is, the data lines DL₁ and DL₂ applying a data voltage to the first sub-pixel electrode PE₁ in the extension direction thereof are alternately changed.

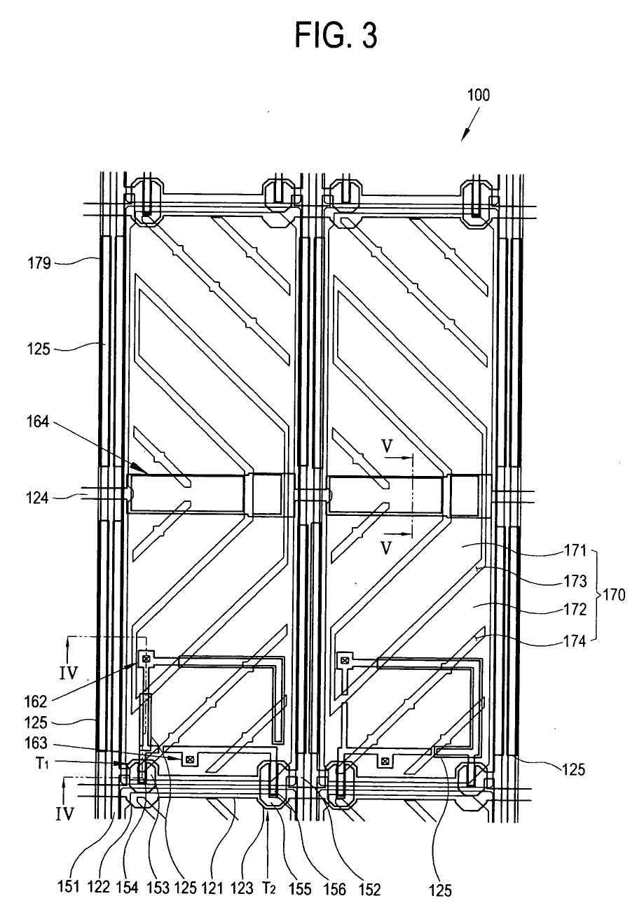

The liquid crystal display device according to the present invention provides improved visibility. The reason of the improved visibility is described with reference to FIG. 3, exemplifying the first pixel P₁.

The first pixel electrode PE₁ receives a first data voltage through the first thin film transistor T₁. The second pixel electrode PE₂ receives a second data voltage different from the first data voltage through the second thin film transistor T₂. That is, the single pixel forms two domains which receive different data voltages.

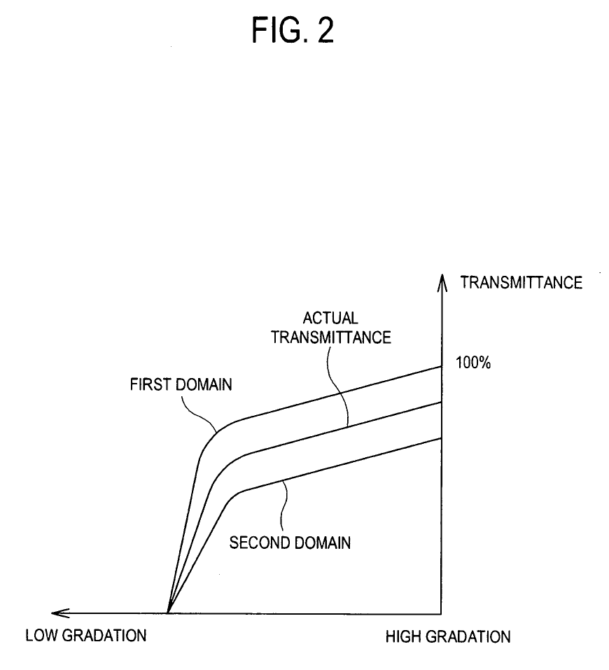

As shown in FIG. 2, the single pixel forms a first domain which corresponds to the first sub-pixel electrode PE₁ and has high brightness, and a second domain which corresponds to the second sub-pixel electrode PE₂ and has low brightness.

That is, the single pixel includes a plurality of domains having different gamma curves. Thus, front and lateral brightness and color compensate for each other, thereby improving lateral visibility.

Hereinafter, a liquid crystal display device according to the first exemplary embodiment of the present invention will be described with reference to FIGS. 3 to 5.

As shown therein, a liquid crystal display device 1 according to the first exemplary embodiment of the present invention includes a first substrate 100, a second substrate 200 facing the first substrate 100, a liquid crystal layer 300 interposed between the first and second substrates 100 and 200, and a light source 400.

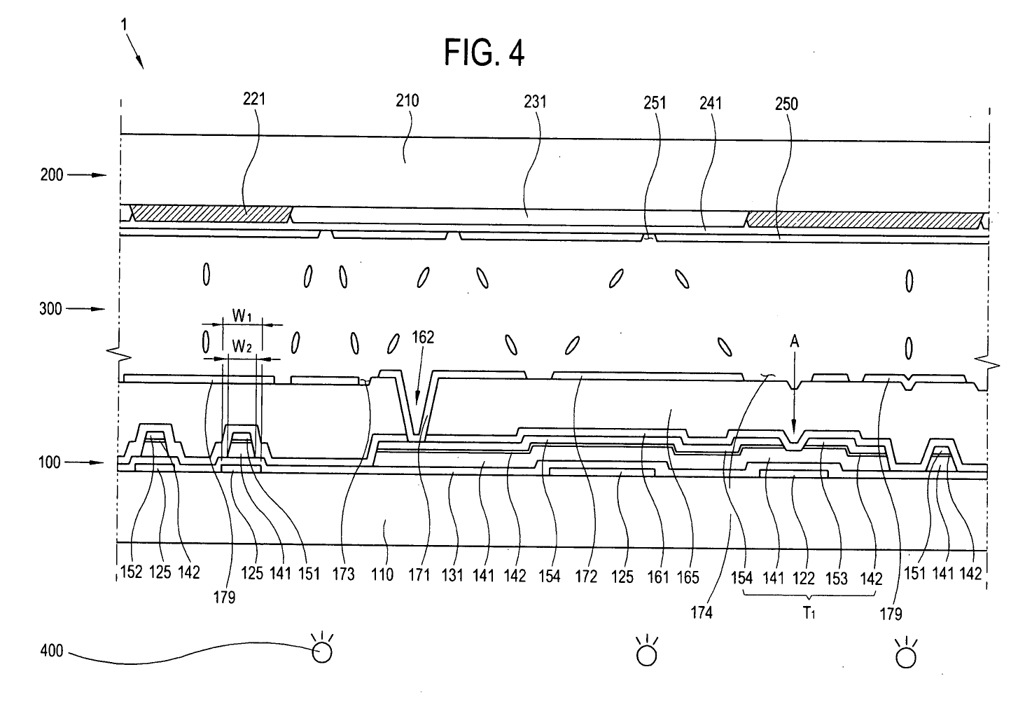

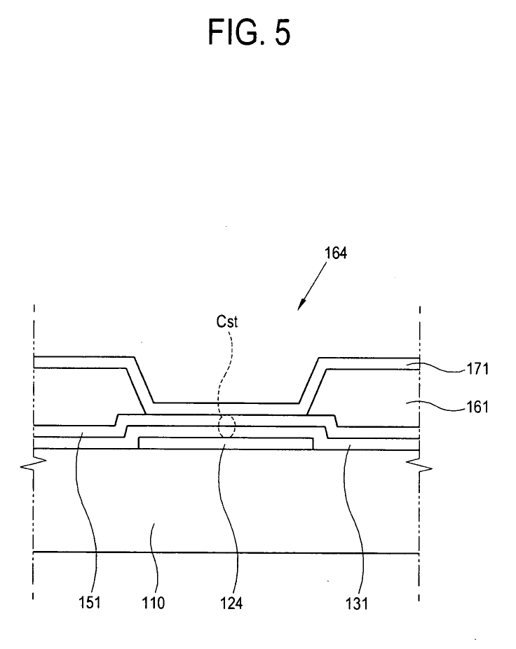

FIG. 3 illustrates only the arrangement of the first substrate 100 for convenience of description. FIGS. 4 and 5 are sectional views of the first substrate 100, and illustrate the second substrate 200 and the liquid crystal layer 300 of the liquid crystal display device 1 which are not shown in FIG. 3, for convenience of description.

First, the first substrate 100 will be described with reference to FIGS. 3 to 5.

As shown in FIGS. 3 and 4, gate wires 121, 122, 123, 124 and 125 are disposed on a first insulating layer 110. The gate wires 121, 122, 123, 124 and 125 may include a metal single or multiple layers. The gate wires 121, 122, 123, 124 and 125 include a gate line 121 which extends transversely, a first gate electrode 122 and a second gate electrode 123 which are connected with the gate line 121, respectively, a storage electrode line 124 which extends in parallel with the gate line 121 and crosses the pixel, and a light blocking layer 125. The light blocking layer 125 is described later in detail.

A gate insulating layer 131 which includes silicon nitride (SiNx) covers the gate wires 121, 122, 123, 124 and 125 on the first insulating layer 110.

A semiconductor layer 141, which includes a semiconductor material such as amorphous silicon, is formed on the gate insulating layer 131. An ohmic contact layer 142, which includes a silicide or n+ hydrogenated amorphous silicon highly doped with an n-type dopant, is disposed on the semiconductor layer 141. The ohmic contact layer 142 is removed from a channel indicated by reference character A between a first source electrode 153 and a first drain electrode 154, and between a second source electrode 155 and a second drain electrode 156.

Data wires 151, 152, 153, 154, 155 and 156 are disposed on the semiconductor layer 141, the ohmic contact layer 142 and the gate insulating layer 131. The data wires 151, 152, 153, 154, 155 and 156 may include metal single layer or multiple layers.

The data wires 151, 152, 153, 154, 155 and 156 and the semiconductor layer 141 directly contact the ohmic contact layer 142 disposed between the semiconductor layer 141 and the data wires 151, 152, 153, 154, 155 and 156.

The data wires 151, 152, 153, 154, 155 and 156 include a first data line 151 and a second data line 152 which are perpendicular to the gate line 121 and define a pixel. First source electrode 153 is branched from the first data line 151 and extends to the channel A, the first drain electrode 154 which is separated from the first source electrode 153, the second source electrode 155 which is branched from the second data line 152 and extends to the channel A, and the second drain electrode 156 which is separated from the second source electrode 155. The first drain electrode 154 is electrically connected with the first data line 151. The second drain electrode 156 is electrically connected with the second data line 152.

The first gate electrode 122, the first source electrode 153 and the first drain electrode 154 form the first thin film transistor T₁. The second gate electrode 123, the second source electrode 155 and the second drain electrode 156 form the second thin film transistor T₂.

The first thin film transistor T₁ is connected with the first data line 151 which is formed in the left side of the pixel. The second thin film transistor T₂ is connected with the second data line 152 which is formed in the right side of the pixel.

A passivation layer 161 is formed on the data wires 151, 152, 153, 154, 155 and 156 and the semiconductor layer 141 not covered by the data wires 151, 152, 153, 154, 155 and 156. The passivation layer 161 may include silicon nitride (SiNx).

An organic layer 165 is formed on the passivation layer 161. The organic layer 165 is thicker than the gate insulating layer 131 and the passivation layer 161, and may be formed by spin coating, slit coating, screen printing, etc. The organic layer 165 may include one of benzocyclobutene (BCB) series, olefin series, acrylic resin series, polyimide series, fluororesin.

A first contact hole 162, a second contact hole 163 and an opening 164 (refer to FIG. 5) are formed in the organic layer 165. The first and second contact holes 162 and 163 expose the first and second drain electrodes 154 and 156 therethrough, respectively. The opening 164 exposes the passivation layer 161 corresponding to a storage electrode line 124. The passivation layer 161 is removed from the first and second contact holes 162 and 163.

The respective drain electrodes 154 and 156 are elongated in a branch shape. The respective drain electrodes 154 and 156 have an elongated part from the contact holes 162 and 163 to the outside of the thin film transistors T₁ and T₂.

As shown in FIG. 5, a pixel electrode 170 (described below) is disposed adjacently to the storage electrode line 124 through the opening 164. The organic layer 165 does not exist between the pixel electrode 170 and the storage electrode line 124. A storage capacitance Cst which is shown in FIG. 5 is formed between the pixel electrode 170 receiving the pixel voltage, and the storage electrode line 124 receiving a common voltage.

The opening 164 is disposed on the storage electrode line 124 because the organic layer 165 is thick and has low permittivity, thereby hardly forming the storage capacitance Cst between the pixel electrode 170 and the storage electrode line 124.

Turning back to FIGS. 3 and 4, the pixel electrode 170 and a shield electrode 179 are disposed on the organic layer 165.

The pixel electrode 170 typically includes a transparent conductive material such as indium tin oxide (ITO) or indium zinc oxide (IZO). The pixel electrode 170 is substantially shaped like a rectangle, and is vertically symmetrical.

The pixel electrode 170 includes a first sub-pixel electrode 171 and a second sub-pixel electrode 172 which are separated from each other by a pixel electrode separating pattern 173. The first sub-pixel electrode 171 is shaped like a bracket and disposed in the center area of the pixel. The second sub-pixel electrode 172 surrounds the first sub-pixel electrode 171.

The second sub-pixel electrode 172 is larger than the first sub-pixel electrode 171. The storage electrode line 124 overlaps the second sub-pixel electrode 172 more than the first sub-pixel electrode 171 since a domain corresponding to the larger second sub-pixel electrode 172 requires larger storage capacitance Cst.

A pixel electrode cutting pattern 174 which is parallel to the pixel electrode separating pattern 173 is formed in the first and second sub-pixel electrodes 171 and 172, respectively.

The first sub-pixel electrode 171 in the left pixel contacts the first drain electrode 154 of the first thin film transistor T₁ through the first contact hole 162, and is electrically connected therewith. The second sub-pixel electrode 172 in the left pixel contacts the second drain electrode 156 of the second thin film transistor T₂ through the second contact hole 163, and is electrically connected therewith.

The first sub-pixel electrode 171 in the neighboring right pixel is electrically connected with the second drain electrode 156 of the second thin film transistor T₂ through the first contact hole 162. The second sub-pixel electrode 172 in the neighboring right pixel is electrically connected with the first drain electrode 154 of the first thin film transistor T₁ through the second contact hole 163.

The pixel electrode 170 receives a voltage from the first and second drain electrodes 154 and 156. The polarities of the voltage applied to the first and second sub-pixel electrodes 171 and 172 may be opposite to each other.

The voltage applied to the first sub-pixel electrode 171 is larger than that applied to the second sub-pixel electrode 172. Thus, lateral visibility of the liquid crystal display device 1 improves.

Here, “larger (smaller) voltage” means that there is a large difference between a data voltage and a common voltage. Conversely, “smaller (lower) data voltage” refers to a small difference between the data voltage and the common voltage.

The pixel electrode separating pattern 173 and the pixel electrode cutting pattern 174 divide the liquid crystal layer 300 into a plurality of sub-domains, together with a common electrode cutting pattern 251 (to be described later). The sub-domains according to the present invention are surrounded by the patterns 173, 174 and 251, and extend in an oblique line.

The shield electrode 179 is formed between the neighboring pixel electrodes 170, i.e. on a boundary between pixels. The shield electrode 179 is in the same layer as the pixel electrode 170.

The shield electrode 179 is disposed in an extension direction of the first and second data lines 151 and 152.

The shield electrode 179 shields the first and second data lines 151 and 152. The pixel electrode 170 is not formed in the boundary area in which the shield electrode 179 is disposed. Thus, the liquid crystal layer 300 in the boundary area is not controlled.

The shield electrode 179 receives a common voltage, and an electric field is not formed between the shield electrode 179 and the common electrode 250.

Typically, the liquid crystal layer 300 which is disposed on the data lines 151 and 152 has different features by the electric field of the data lines 151 and 152, compared to the liquid crystal layer 300 disposed on the pixel electrode 170. That is, the liquid crystal layer 300 which is disposed on the data lines 151 and 152 is hardly controlled, thereby causing errors such as light leakage.

As the electric field is not formed between the shield electrode 179 and the common electrode 250, the liquid crystal layer 300 maintains its initial state. In a normally-black mode, the liquid crystal layer 300 disposed between the shield electrode 179 and the common electrode 250 always displays black not to cause the light leakage.

Hereinafter, the second substrate 200 is described with reference to FIG. 4.

As shown therein, a black matrix 221 is disposed on a second insulating substrate 210. The black matrix 221 may include a photoresist organic material added with a black pigment. The black pigment may include carbon black or titanium oxide.

The black matrix 221 is disposed on the thin film transistors T₁ and T₂, and the shield electrode 179.

A color filter 231 is disposed on the black matrix 221 and the second insulating substrate 210. The color filter 231 may include sub-layers having different colors, such as red, green and blue.

An overcoat layer 241 is disposed on the color filter 231. The overcoat layer 241 provides planar surface.

The common electrode 250 is disposed on the overcoat layer 241. The common electrode 250 is comprised of a transparent conductive material such as ITO or IZO. The common electrode 250 directly applies a voltage to the liquid crystal layer 300 together with the pixel electrode 170 of the first substrate 100.

The common electrode cutting pattern 251 is formed in the common electrode 250. The common electrode cutting pattern 251 partially forms the plurality of sub-domains together with the pixel electrode separating pattern 173 and the pixel electrode cutting pattern 174.

The foregoing patterns 173, 174 and 251 are not limited to those according to the exemplary embodiment, and may vary.

Hereinafter, the liquid crystal layer 300 will be described with reference to FIG. 4.

As shown therein, the liquid crystal layer 300 is interposed between the first and second substrates 100 and 200. The liquid crystal layer 300 is a vertically-aligned (VA) mode. In the VA mode, a long axis of liquid crystal molecules is vertical to the first and second substrates 100 and 200 while a voltage is not applied thereto.

If the voltage is applied, the liquid crystal molecules lie in a vertical direction with respect to the electric field due to negative dielectric anisotropy.

If the patterns 173, 174 and 251 of the liquid crystal display device 1 according to the first exemplary embodiment of the present invention are not formed, the liquid crystal molecules are irregularly aligned since the lying direction thereof is not determined, thereby creating a disclination line on a boundary between different lying directions.

A fringe field is formed by the patterns 173, 174 and 251 when the voltage is applied to the liquid crystal layer 300, thereby determining the lying direction of the liquid crystal molecules.

Hereinafter, the light blocking layer 125 of the liquid crystal display device 1 according to the first exemplary embodiment of the present invention is described in detail with reference to FIGS. 3 and 4.

As described above, the light blocking layer 125 is disposed in the same layer as the gate line 121, the first gate electrode 122, the second gate electrode 123 and the storage electrode line 124.

The light blocking layer 125 is disposed between the first insulating layer 110, and the semiconductor layer 141 corresponding to the data wires 151, 152, 153, 154, 155 and 156.

The light blocking layer 125 floats, i.e., is not connected with other power sources. The light blocking layer 125 is shaped like an island, and does not contact the gate line 121, the first gate electrode 122, the second gate electrode 123 and the storage electrode line 124.

The width W₁ of the light blocking layer 125 which overlaps the semiconductor layer 141 is wider than the width W₂ of the semiconductor layer 141. Thus, the light blocking layer 125 blocks light emitted from the light source 400 to the semiconductor layer 141 overlapping the light blocking layer 125.

The light blocking layer 125 is formed corresponding to the first and second data lines 151 and 152 shielded by the shied electrode 179, corresponding to the shield electrode 179.

The light blocking layer 125 in the left pixel is disposed below the first drain electrode 154 overlapping the second sub-pixel electrode 172. The light blocking layer 125 in the right pixel is disposed below the second drain electrode 156 overlapping the second sub-pixel electrode 172.

The light blocking layer 125 in the left pixel is not disposed between the second drain electrode 156 and the first insulating substrate 110. The light blocking layer 125 in the right pixel is not disposed between the first drain electrode 154 and the first insulating substrate 110.

Hereinafter, the effect of the light blocking layer 125 of the liquid crystal display device 1 according to the first exemplary embodiment of the present invention will be described with reference to FIG. 4.

If light is emitted to the semiconductor layer 141, permittivity of the semiconductor layer 141 rises.

If the permittivity of the semiconductor layer 141 rises, the electrical capacitance between the pixel electrode 170 corresponding to the semiconductor layer 141 and the data wires 151, 152, 153, 154, 155 and 156 increases, thereby lowering the voltage flowing through the data wires 151, 152, 153, 154, 155 and 156.

If the voltage of the data wires 151, 152, 153, 154, 155 and 156 is lowered, an error is generated in a signal applied to the pixel electrode 170 and display quality is lowered, too.

Particularly, the first drain electrode 154 which is electrically connected with the first sub-pixel electrode 171 overlaps the second sub-pixel electrode 172 in the left pixel of the liquid crystal display device 1 according to the first exemplary embodiment of the present invention. Thus, if light is emitted to the semiconductor layer 141 corresponding to the first drain electrode 154, there is a high possibility of lowering the voltage of the first drain electrode 154.

Like in the left pixel, the second drain electrode 156 which is electrically connected with the first sub-pixel electrode 171 overlaps the second sub-pixel electrode 172 in the right pixel. Thus, if light is emitted to the semiconductor layer 141 corresponding to the second drain electrode 156, there is a high possibility of lowering the voltage of the second drain electrode 156.

However, the light blocking layer 125 of the liquid crystal display device 1 according to the first exemplary embodiment of the present invention is disposed between the semiconductor layer 141 corresponding to the first and second data lines 151 and 152, and the first insulating substrate 110, thereby minimizing light supplied to the semiconductor layer 141 corresponding to the first and second data lines 151 and 152. Also, the lowering of the voltage of the first and second data lines 151 and 152 is minimized, too.

The light blocking layer 125 in the left pixel is disposed between the semiconductor layer 141 corresponding to the first drain electrode 154 overlapped with the second sub-pixel electrode 172 and the first insulating layer 110. Thus, the lowering of the voltage applied to the first sub-pixel electrode 171 in the left pixel is minimized. The light blocking layer 125 is not disposed between the second drain electrode 156 and the first insulating substrate 110, thereby minimizing a decline in an aperture ratio of the left pixel due to the light blocking layer 125. The second drain electrode 156 has a lower possibility of being lowered in voltage than the first drain electrode 154 is.

The light blocking layer 125 in the right pixel is disposed between the semiconductor layer 141 corresponding to the second drain electrode 156 overlapped with the second sub-pixel electrode 172 and the first insulating layer 110. Thus, the lowering of the voltage applied to the first sub-pixel electrode 171 in the right pixel is minimized. The light blocking layer 125 is not disposed between the first drain electrode 154 and the first insulating substrate 110, thereby minimizing a decline in an aperture ratio of the right pixel due to the light blocking layer 125. The first drain electrode 154 has a lower possibility of being lowered in voltage than the second drain electrode 156 is.

Meanwhile, the liquid crystal display device 1 according to the first exemplary embodiment of the present invention may be driven at 120 Hz and above frequency.

If the frequency is larger, motion picture quality improves while electrical interference between the pixel electrode 170 and the data wires 151, 152, 153, 154, 155 and 156 increases.

However, according to the first exemplary embodiment of the present invention, the electrical interference between the pixel electrode 170 and the data wires 151, 152, 153, 154, 155 and 156 is minimized by the light blocking layer 125. Thus, the lowering of the display quality is minimized even if the frequency of the liquid crystal display device 1 increases.

Hereinafter, a manufacturing method of the liquid crystal display device 1 according to the first exemplary embodiment of the present invention will be described with reference to FIGS. 3, 4 and 6 to 10.

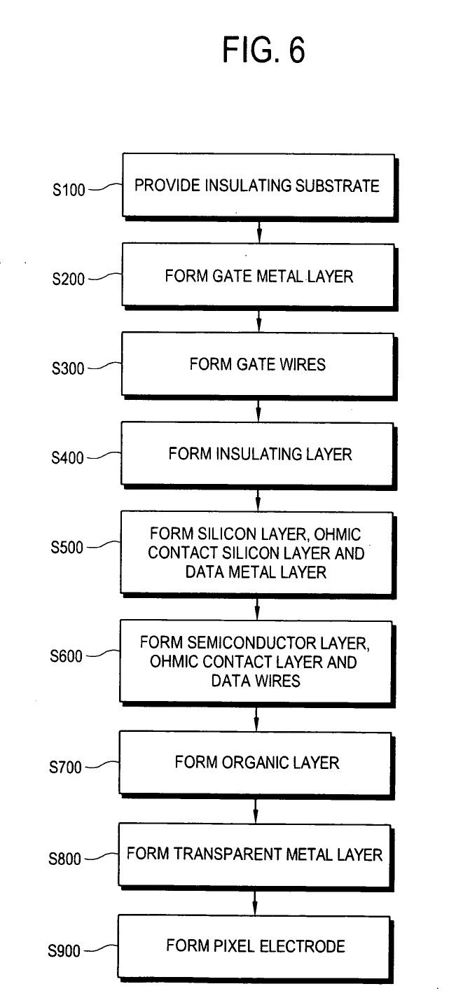

As shown in FIG. 6, the manufacturing method of the liquid crystal display device 1 according to the first exemplary embodiment of the present invention includes an operation S100 of providing the insulating substrate, an operation S200 of forming a gate metal layer, an operation S300 of forming the gate wires 121, 122, 123, 124 and 125, an operation S400 of forming the insulating layer, an operation S500 of forming a silicon layer, an ohmic contact silicon layer and a data metal layer, an operation S600 of forming the semiconductor layer 141, the ohmic contact layer 142 and the data wires 151, 152, 153, 154, 155 and 156, an operation S700 of forming the organic layer 165, an operation S800 of forming the transparent metal layer and an operation S900 of forming the pixel electrode 170.

Hereinafter, the focus is given to the manufacturing method of the first substrate 100.

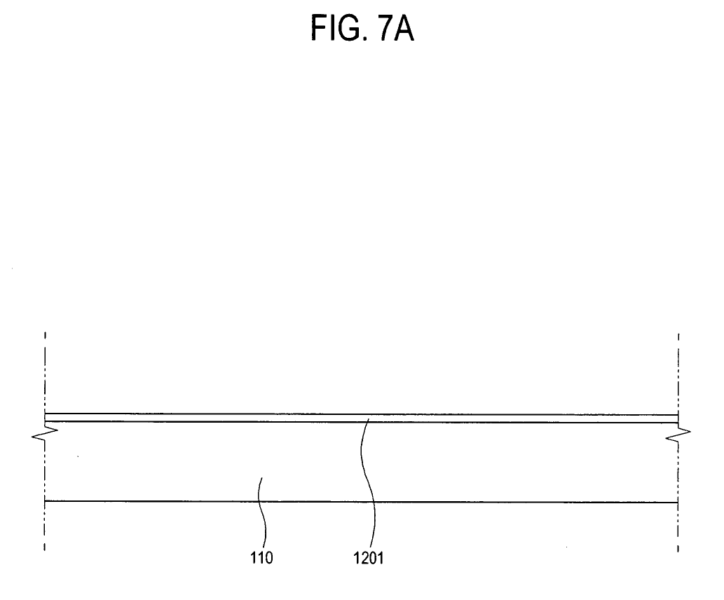

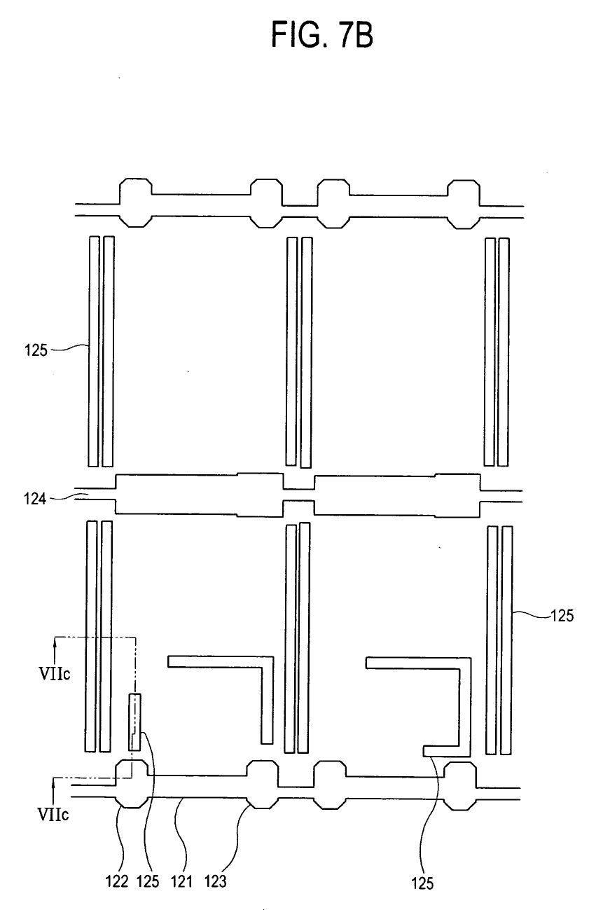

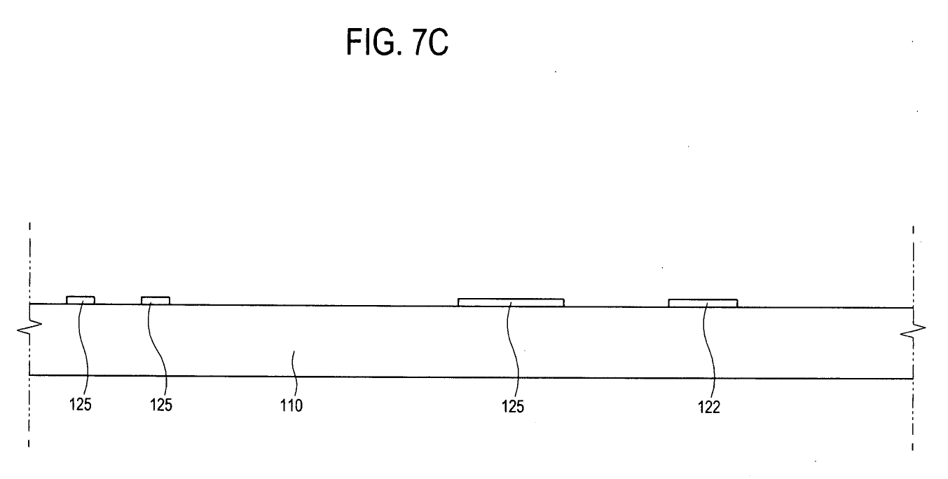

First, the first insulating substrate 110 is provided as shown in FIG. 7A (S100).

The first insulating substrate 110 may include amorphous glass or polymer. Preferably, the first insulating substrate 110 may include a heat resistant material which resists high temperature processes.

Then, a gate metal layer 1201 is formed on the first insulating layer 110 (S200).

The gate metal layer 1201 may include metal single or multiple layers. The gate metal layer 1201 is deposited on the first insulating layer 110 by deposition such as sputtering.

As shown in FIGS. 7B and 7C, the gate metal layer 1201 is patterned to form the gate wires 121, 122, 123, 124 and 125 (S300).

The gate metal layer 1201 is patterned by photolithography to form the gate wires 121, 122, 123, 124 and 125 including the gate line 121, the first gate electrode 122, the second gate electrode 123, the storage electrode line 124 and the light blocking layer 125.

The light blocking layer 125 is formed corresponding to the first data line 151, the second data line 152, the first drain electrode 154 in the left pixel and the second drain electrode 156 in the right pixel which will be formed later.

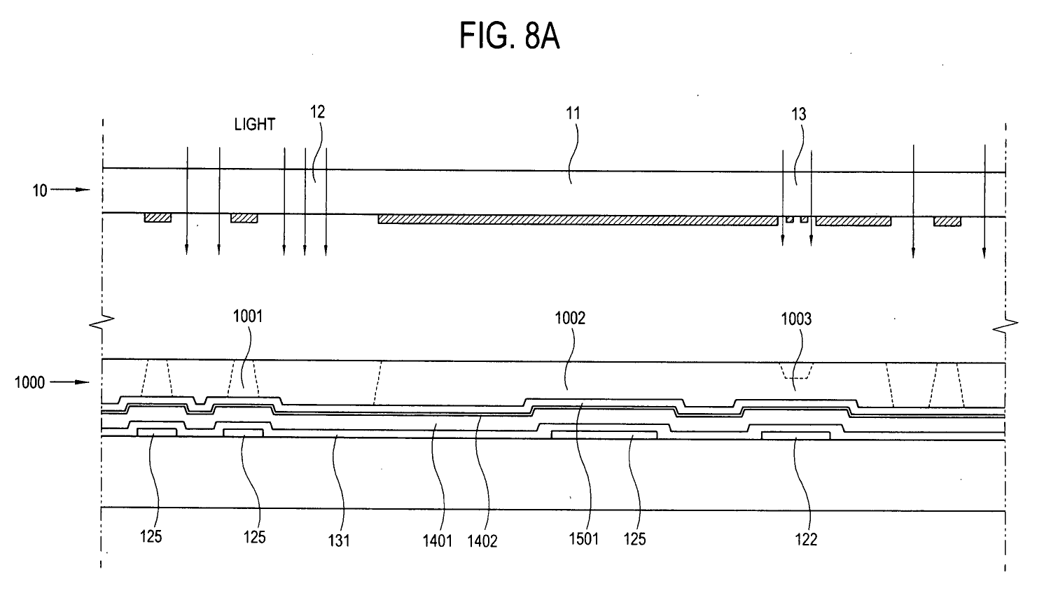

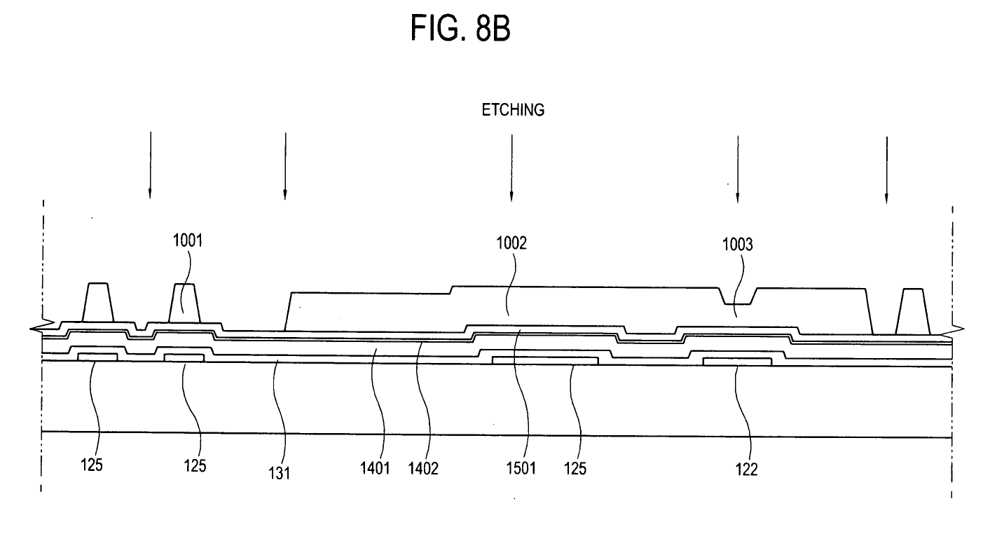

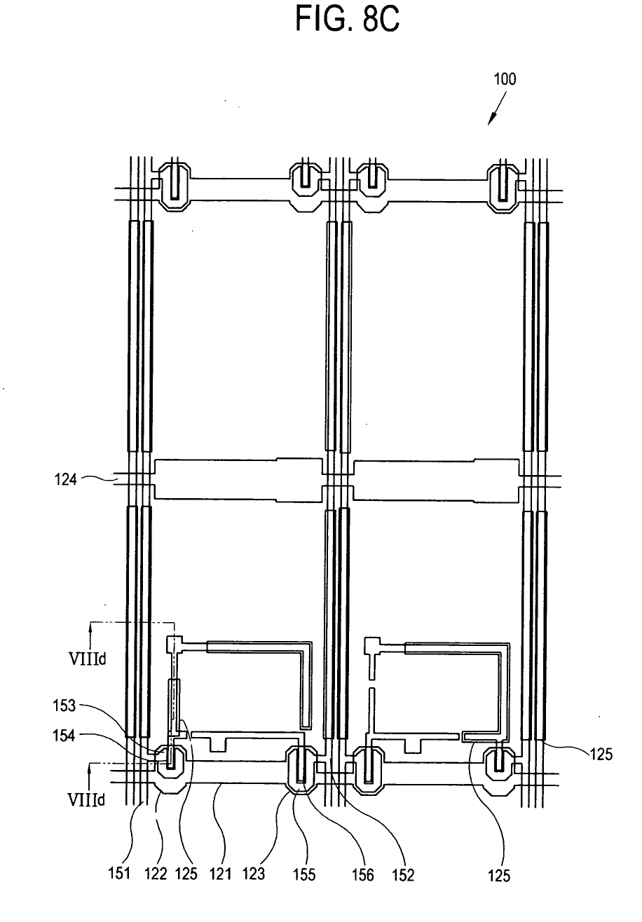

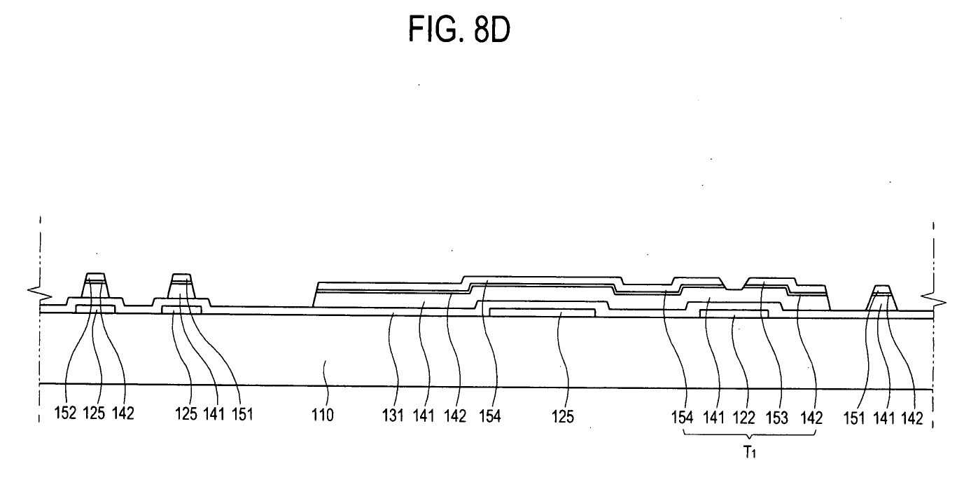

As shown in FIG. 8A, the gate insulating layer 131 is formed on the gate wires 121, 122, 123, 124 and 125 and the first insulating layer 110 (S400).

The gate insulating layer 131 includes silicon nitride (SiNx).

As shown in FIG. 8A, a silicon layer 1401, an ohmic contact silicon layer 1402 and a data metal layer 1501 are formed on the gate insulating layer 131 (S500).

Like the gate metal layer 1201, the silicon layer 1401, the ohmic contact silicon layer 1402 and the data metal layer 1501 are deposited by deposition such as sputtering.

As shown in FIGS. 8A to 8D, the silicon layer 1401, the ohmic contact silicon layer 1402 and the data metal layer 1501 are formed as the semiconductor layer 141, the ohmic contact layer 142 and the data wires 151, 152, 153, 154, 155 and 156, respectively (S600). Hereinafter, the process of forming the semiconductor layer 141, the ohmic contact layer 142 and the data wires 151, 152, 153, 154, 155 and 156 will be described in detail.

As shown in FIG. 8A, a photoresist layer 1000 is applied to the data metal layer 1501, and then receives light through a single mask 10. Then, the photoresist layer 1000 is developed. As shown in FIG. 8B, photoresist patterns 1001, 1002 and 1003 are formed. The photoresist patterns 1001, 1002 and 1003 include a first sub-photoresist layer pattern 1001, a second sub-photoresist layer pattern 1002 and a third sub-photoresist layer pattern 1003.

The single mask 10 which is used to form the photoresist layer patterns 1001, 1002 and 1003 includes a light blocking area 11, a light transmitting area 12 and a channel area 13.

The photoresist layer 1000 corresponding to the light blocking area 11 remains after exposing and developing processes to form the first and second sub-photoresist layer patterns 1001 and 1002. The photoresist layer 1000 corresponding to the light transmitting area 12 is removed during the exposing and developing processes. The photoresist layer 1000 corresponding to the channel area 13 remains after the exposing and developing processes to form the third sub-photoresist layer pattern 1003. The third sub-photoresist layer pattern 1003 has a thickness thinner than the first and second sub-photoresist layer patterns 1001 and 1002 do.

As shown in FIG. 8B, the silicon layer 1401, the ohmic contact silicon layer 1402 and the data metal layer 1501 are etched using the photoresist layer patterns 1001, 1002 and 1003. Then, the semiconductor layer 141, the ohmic contact layer 142 and the data wires 151, 152, 153, 154, 155 and 156 are formed as shown in FIGS. 8C and 8D.

As shown in FIGS. 8B to 8D, the first sub-photoresist layer pattern 1001 corresponds to the first and second data lines 151 and 152. The second sub-photoresist layer pattern 1002 corresponds to the first drain electrode 154. The third sub-photoresist layer pattern 1003 corresponds to the channel A of the first thin film transistor T₁.

As described above, the semiconductor layer 141, the ohmic contact layer 142 and the data wires 151, 152, 153, 154, 155 and 156 are formed by the single mask 10. That is, the single photoresist layer 1000 is used, and the semiconductor layer 141 is formed below the data wires 151, 152, 153, 154, 155 and 156 corresponding thereto. Meanwhile, the data wires 151, 152, 153, 154, 155 and 156 are not formed in the channel A on the semiconductor layer 141.

The single mask 10 which is used in manufacturing of the liquid crystal display device 1 according to the first exemplary embodiment of the present invention includes a slit mask. According to another exemplary embodiment, a semi-transparent mask may be used.

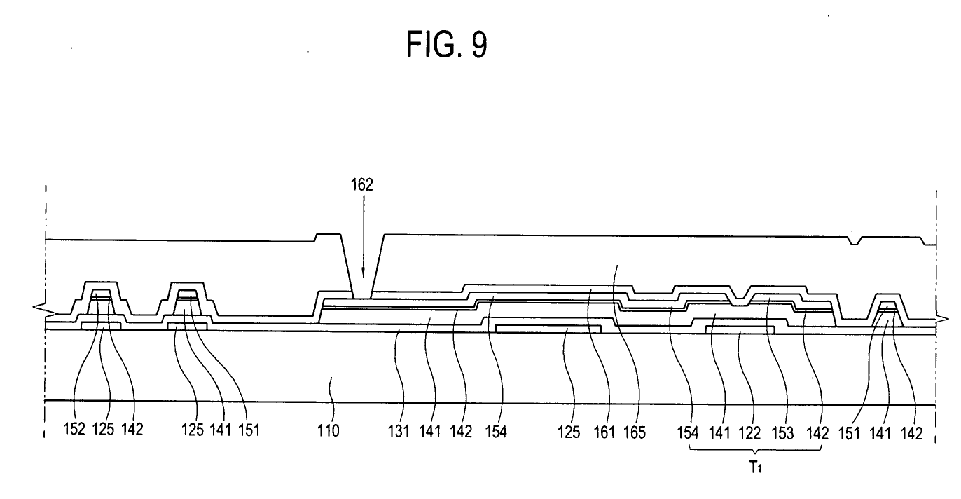

As shown in FIG. 9, the passivation layer 161 and the organic layer 165 are sequentially formed (S700).

The first contact hole 162 is formed by photolithography. Even though it is not shown in FIG. 9, the second contact hole 163 and the opening 164 in FIG. 3 are also formed together with the first contact hole 162. The first and second drain electrodes 154 and 156 are exposed by the first and second contact holes 162 and 163 by removing the organic layer 165 and the passivation layer 161. The passivation layer 161 is exposed by the opening 164 as the organic layer 165 is removed therefrom.

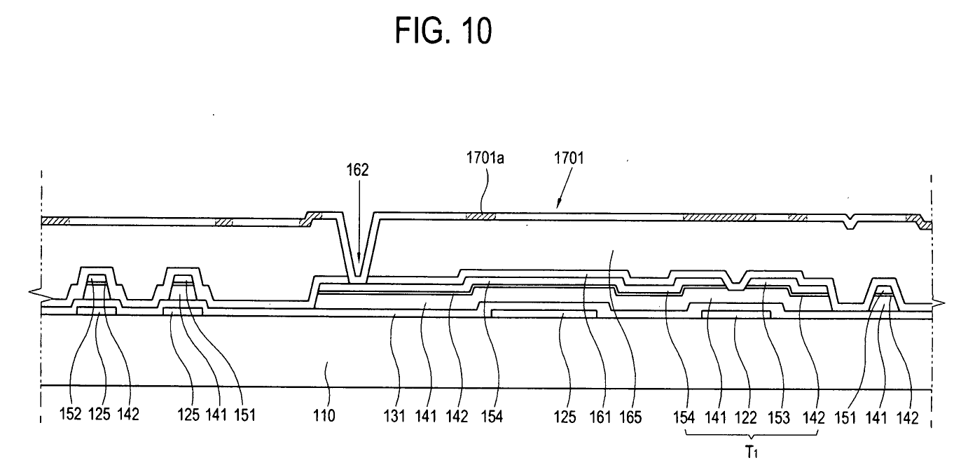

As shown in FIG. 10, a transparent metal layer 1701 is formed (S800).

The transparent metal layer 1701 is formed by deposition. Typically, the transparent metal layer 1701 includes a transparent conductive material such as ITO or IZO.

As shown in FIGS. 3, 4 and 10, the transparent metal layer 1701 is patterned to form the pixel electrode 170 (S900).

A removing part 1701a of the transparent metal layer 1701 is removed by photolithography as shown in FIG. 10, to form the pixel electrode 170 in FIGS. 3 and 4.

The shield electrode 179 is formed together with the pixel electrode 170.

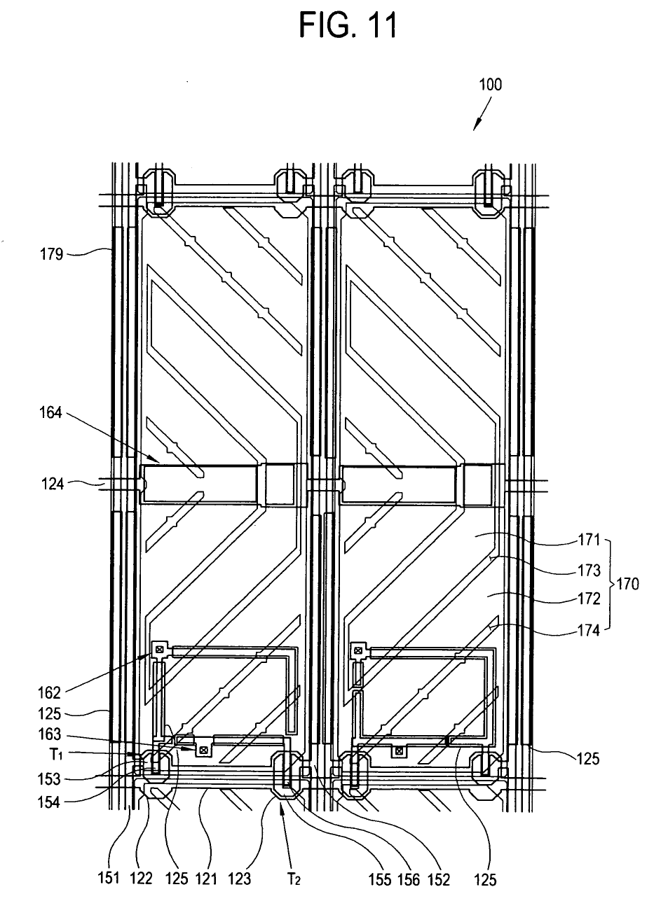

Hereinafter, a liquid crystal display device according to second to fourth exemplary embodiments of the present invention will be described with reference to FIGS. 11 to 13.

The liquid crystal display device according to the second exemplary embodiment of the present invention will be described with reference to FIG. 11.

As shown therein, a light blocking layer 152 is formed between a first insulating layer 110 and a semiconductor layer 141 corresponding to a first data line 151, a second data line 152, a first drain electrode 154 and a second drain electrode 156.

The light blocking layer 125 is formed corresponding to the first and second drain electrodes 154 and 156. Thus, the lowering of a voltage applied to the first and second sub-pixel electrodes 171 and 172 of the respective pixels through the first and second drain electrodes 154 and 156 is minimized.

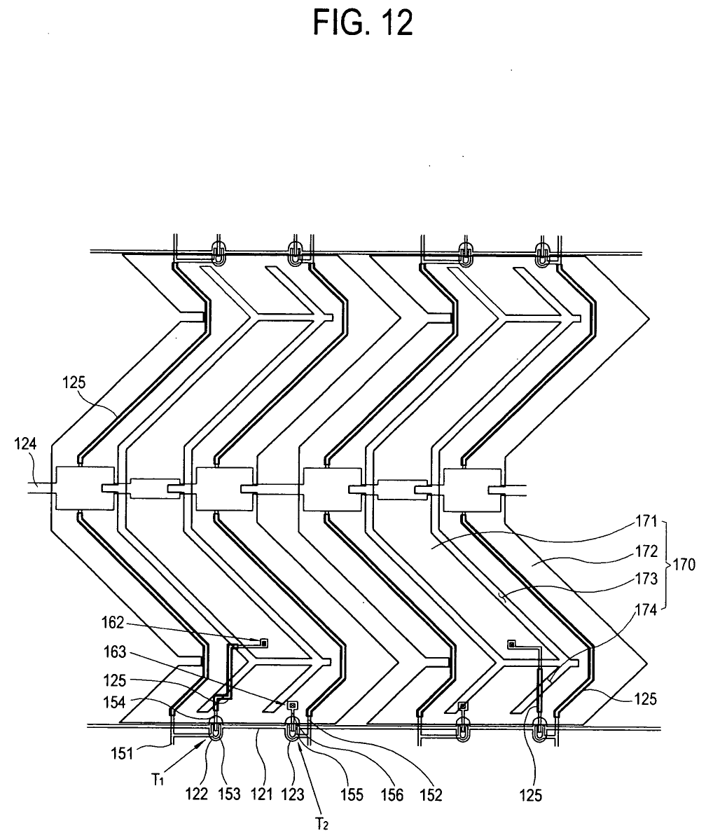

The liquid crystal display device according to the third exemplary embodiment of the present invention will be described with reference to FIG. 12.

As shown therein, a pixel electrode 170 is elongated in an extension direction of a first data line 151 and a second data line 152, and bent by three times. The pixel electrode 170 is vertically symmetrical.

The first and second data lines 151 and 152 overlap the pixel electrode 170, instead of being disposed outside of the pixel electrode 170. More specifically, the first and second data lines 151 and 152 overlap the second sub-pixel electrode 172 of the pixel electrode 170.

The light blocking layer 125 is disposed between the semiconductor layer 141 corresponding to the first and second data lines 151 and 152, and the first insulating layer 110 in respective pixels.

The light blocking layer 125 in the left pixel is further disposed between the first insulating layer 110 and the semiconductor layer 141 corresponding to the first drain electrode 154 overlapping the second sub-pixel electrode 172, the first data line 151 and the second data line 152.

The light blocking layer 125 in the right pixel is further disposed between the first insulating layer 110 and the semiconductor layer 141 corresponding to the second drain electrode 156 overlapping the second sub-pixel electrode 172, the first data line 151 and the second data line 152.

According to the present invention, as the first and second data lines 151 and 152 are disposed within the pixel electrode 170, an additional shield electrode 179 is not required. The light blocking layer 125 corresponds to the first and second data line 151 and 152 disposed within the pixel electrode 170, thereby improving an aperture ratio.

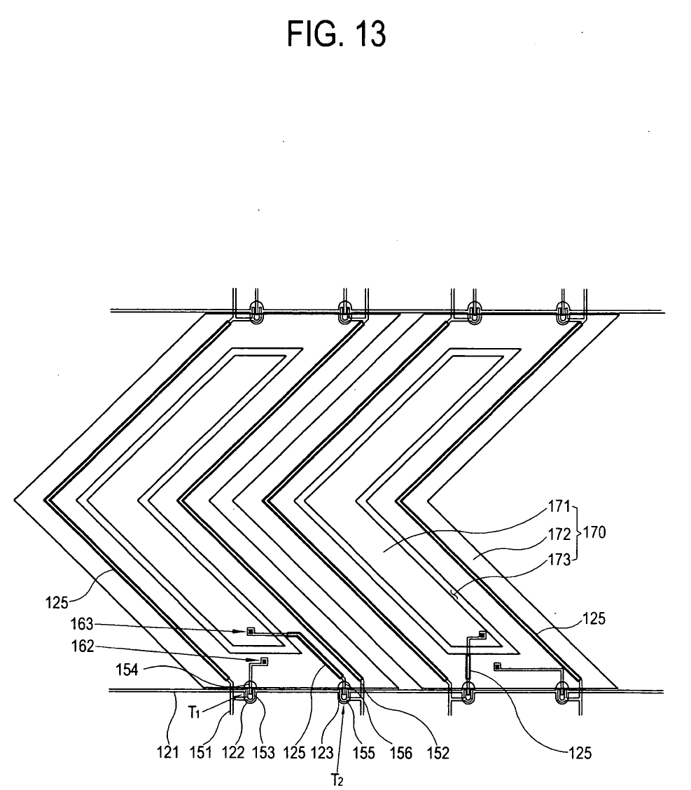

The liquid crystal display device according to a fourth exemplary embodiment of the present invention will be described with reference to FIG. 13.

As shown therein, a pixel electrode 170 is elongated in an extension direction of a first data line 151 and a second data line 152. The pixel electrode 170 is shaped like a bracket, and is bent once.

A first sub-pixel electrode 171 is elongated in an extension direction of the first data line 151 and the second data line 152. The first sub-pixel electrode 171 is shaped like a bracket, and is bent once. The second sub-pixel electrode 172 surrounds the first sub-pixel electrode 171.

The first and second data lines 151 and 152 cross the second sub-pixel electrode 172.

According to another exemplary embodiment, the pixel electrode 170 may be bent by twice or three times or more.

According to another exemplary embodiment, the first and second data lines 151 and 152 may be elongated along a circumference of the pixel electrode 170 that is bent once and above.

As described above, the present invention provides a liquid crystal display device which minimizes light supplied to a semiconductor layer disposed below data wires, and a manufacturing method thereof.

Although a few exemplary embodiments of the present invention have been shown and described, it will be appreciated by those skilled in the art that changes may be made in these exemplary embodiments without departing from the principles and spirit of the invention, the scope of which is defined in the appended claims and their equivalents.

What is claimed is:

1. A liquid crystal display device, comprising:
a first substrate;
a second substrate which faces the first substrate;
a liquid crystal layer which is interposed between the first and second substrates;
the first substrate comprising:
an insulating substrate;
a gate line which is disposed on the insulating substrate;
data wires which comprises first and second data lines insulatedly crossing the gate line, a first drain electrode electrically connected with the first data line, and a second drain electrode electrically connected with the second data line;
a pixel electrode comprising a first sub-pixel electrode electrically connected with one of the first and second drain electrodes, and a second sub-pixel electrode separated from the first sub-pixel electrode and electrically connected with the other one of the first and second drain electrodes;
a semiconductor layer disposed between the data wires and the insulating substrate;
an ohmic contact layer disposed between the semiconductor layer and the data wires, the ohmic contact layer directly contacting the semiconductor layer and the data wires; and
a light blocking layer disposed between at least a part of the data wires and the insulating substrate.

2. The liquid crystal display device according to claim 1, wherein the light blocking layer is disposed between the semiconductor layer and the insulating substrate.

3. The liquid crystal display device according to claim 2, wherein a width of the light blocking layer overlapping the semiconductor layer is wider than a width of the semiconductor layer associated with the light blocking layer.

4. The liquid crystal display device according to claim 1, wherein the light blocking layer is disposed in the same layer as the gate line.

5. The liquid crystal display device according to claim 1, wherein the light blocking layer floats.

6. The liquid crystal display device according to claim 1, wherein the first substrate further comprises a thin film transistor which has a first sub-thin film transistor connected with the gate line and the first data line, and a second sub-thin film transistor connected with the gate line and the second data line; and
the first sub-thin film transistor comprises the first drain electrode, and the second sub-thin film transistor comprises the second drain electrode.

7. The liquid crystal display device according to claim 1, wherein the first and second sub-pixel electrodes are bent at least once at an angle with respect to an extension direction of the first data line or the second data line.

8. The liquid crystal display device according to claim 1, wherein the liquid crystal display device is driven at 120 Hz.

9. The liquid crystal display device according to claim 1, wherein the first and second drain electrodes apply a voltage to their associated sub-pixel electrodes, and
polarities of the voltage applied to the first and second sub-pixel electrodes are opposite to each other.

10. The liquid crystal display device according to claim 1, wherein the first and second drain electrodes apply a voltage to their associated sub-pixel electrodes, and
a magnitude of the voltage applied to the first sub-pixel electrode is larger than a magnitude of the voltage applied to the second sub-pixel electrode.

11. The liquid crystal display device according to claim 1, wherein the first drain electrode contacts the first sub-pixel electrode,
the second sub-pixel electrode surrounds the first sub-pixel electrode, and
the light blocking layer is disposed below the first drain electrode overlapping the second sub-pixel electrode.

12. The liquid crystal display device according to claim 1, wherein the second sub-pixel electrode surrounds the first sub-pixel electrode,
the first data line is disposed in on a first side of the pixel electrode,
the second data line is disposed on a second, opposite side of the pixel electrode, wherein
the second data line is electrically connected with the second sub-pixel electrode in one of the pair of pixel electrodes adjacent to each other toward the gate line, and further wherein
the first data line is electrically connected with the second sub-pixel electrode in the other one of the pair of pixel electrodes.

13. The liquid crystal display device according to claim 1, wherein the light blocking layer is formed corresponding to the first data line, the second data line, the first drain electrode and the second drain electrode.

14. The liquid crystal display device according to claim 1, wherein the light blocking layer is disposed in at least one of: between the insulating substrate and the first drain electrode, and between the insulating substrate and the second drain electrode.

15. The liquid crystal display device according to claim 11, wherein the light blocking layer is not disposed between the second drain electrode and the insulating substrate.

16. The liquid crystal display device according to claim 15, wherein the first and second drain electrodes respectively comprise a first branch electrode elongated to contact the pixel electrode, and a second branch electrode elongated from a contact part of the pixel electrode, and
the light blocking layer is not disposed between the second branch electrode of the first drain electrode, and the insulating substrate.

17. The liquid crystal display device according to claim 11, wherein the second substrate comprises a common electrode,
the pixel electrode comprises a pixel electrode cutting pattern,
the common electrode comprises a common electrode cutting pattern, and
the liquid crystal layer is a vertically-aligned mode.

18. The liquid crystal display device according to claim 11, wherein the pixel electrode is plurally provided, and
the first substrate further comprises a shield electrode which is disposed between adjacent pixel electrodes, and is disposed in an extension direction parallel to the first data line or the second data line.

19. The liquid crystal display device according to claim 18, wherein the light blocking layer is formed along the shield electrode, and corresponds to the first and second data lines, respectively.

20. The liquid crystal display device according to claim 19, wherein the shield electrode is in the same layer as the pixel electrode.

21. A manufacturing method of a liquid crystal display device, the manufacturing method comprising:
providing an insulating substrate;
forming a gate metal layer on the insulating substrate;
forming gate wires having a gate line and a light blocking layer by patterning the gate metal layer;
forming an insulating layer on the gate wires;
forming a silicon layer on the insulating layer;
forming an ohmic contact silicon layer on the silicon layer;
forming a data metal layer on the ohmic contact silicon layer;
forming data wires which partially overlap the light blocking layer, the data wires having a first data line and a second data line insulatedly crossing the gate line, a first drain electrode electrically connected with the first data line, and a second drain electrode electrically connected with the second data line, an ohmic contact layer and a semiconductor layer by patterning the data metal layer, the ohmic contact silicon layer and the silicon layer through a single mask;
forming an organic layer on the semiconductor layer, the ohmic contact layer and the data wires;
forming a transparent metal layer on the organic layer; and
forming a pixel electrode which comprises a first sub-pixel electrode electrically connected with one of the first and second drain electrodes, and a second sub-pixel electrode separated from the first sub-pixel electrode and electrically connected with the other one of the first and second drain electrodes.
